(19) United States
(12) Patent Application Publication
(10) Pub. No.: US 2007/0138612 A1
(43) Pub. Date: Jun. 21, 2007

(54) Stackable electronic device assembly and high G-force test fixture

(75) Inventors: Michael Warner, San Jose, CA (US); Ilyas Mohammed, Santa Clara, CA (US); Ronald Green, San Jose, CA (US); John B. Riley III, Dallas, TX (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/495,287

(22) Filed: Jul. 28, 2006

Related U.S. Application Data
(60) Provisional application No. 60/703,175, filed on Jul. 28, 2005.

(51) Int. Cl. H01L 23/02; H01L 23/48; H01L 23/06; H01L 23/04

(52) U.S. Cl. 257/678; 257/684; 257/778; 257/698

(57) ABSTRACT

A stackable chip assembly is disclosed, as are different embodiments relating to same. The chip assembly preferably includes at least two substrates with components mounted on each. The substrates are preferably situated with respect to one another such that components on one substrate extend towards the other substrate and vice versa. The components of each substrate preferably extend or are interspersed between each other. Different connections between the substrates are disclosed, as well as methods of constructing such chip assemblies. In addition, a high G-force testing fixture is also disclosed for use in testing chip packages or the like.

### CROSS-REFERENCE TO RELATED APPLICATIONS

This application claims the benefit of the filing date of U.S. Provisional Patent Application No. 60/703,175 filed on Jul. 28, 2005 and entitled “STACKABLE ELETRONIC DEVICE ASSEMBLY AND HIGH G-FORCE TEST FIXTURE,” the disclosure of which is hereby incorporated herein by reference. In addition, this application is related to commonly owned United States Utility Provisional Patent Application No. ______ filed on even date herewith, naming William Carlson, Michael Warner, Salvador Tostado, John Riley, III, Ronald Green, Ilyas Mohammed, Michael Nystrom, Rolf Gustus and David Baker and entitled “STACKABLE ELECTRONIC DEVICE ASSEMBLY,” and commonly owned U.S. Provisional Patent Application No. ______ filed on even date herewith, naming Daniel Buckminster, Salvadore Tostado and Apolinar Alvarez, Jr. and entitled “STACKABLE ELECTRONIC DEVICE ASSEMBLY AND METHOD,” the disclosures of which are hereby incorporated herein by reference.

### BACKGROUND OF THE INVENTION

Microelectronic elements such as semiconductor chips are typically provided in packages which provide physical and chemical protection for the semiconductor chip or other microelectronic element. Such a package typically includes a package substrate such as a small circuit panel formed from a dielectric material and having electrically conductive terminals thereon. The chip is preferably mounted on the panel and electrically connected to the terminals of the package substrate. Typically, the chip and portions of the substrate are covered by an encapsulant or overmolding, so that only the terminal-bearing outer surface of the substrate remains exposed. Such a package can be readily shipped, stored and handled. The package can be mounted to a larger circuit panel such as a circuit board using standard mounting techniques, most typically surface-mounting techniques. Considerable effort has been devoted in the art to making such packages smaller, so that the packaged chip occupies a smaller area on the circuit board. For example, packages referred to as chip-scale packages occupy an area of the circuit board equal to the area of the chip itself, or only slightly larger than the area of the chip itself. However, even with chip-scale packages, the aggregate area occupied by several packaged chips is greater than or equal to the aggregate area of the individual chips.

It has been proposed to provide “stacked” packages, in which a plurality of individual chip packages or units are mounted one above the other in a common package assembly. This common package assembly can be mounted on an area of the circuit panel which may be equal to or just slightly larger than the area typically required to mount a single package or unit containing a single chip. This stacked package approach conserves space on the circuit panel. Chips or other elements which are functionally related to one another can be provided in a common stacked package assembly. The assembly may incorporate interconnections between these elements. Thus, the main circuit panel to which the assembly is mounted need not include the conductors and other elements required for these interconnections. This, in turn, allows use of a simpler circuit panel and, in some cases, allows the use of a circuit panel having fewer layers of metallic connections, thereby materially reducing the cost of the circuit panel. Moreover, the interconnections within a stacked package assembly often can be made with lower electrical impedance and shorter signal propagation delay times than comparable interconnections between individual units mounted on a circuit panel. This, in turn, can increase the speed of operation of the microelectronic elements within the stacked package as, for example, by allowing the use of higher clock speeds in signal transmissions between these elements.

One form of stacked package assembly which has been proposed heretofore is sometimes referred to as a “ball stack.” A ball stack assembly includes two or more individual units. Each unit incorporates a unit substrate similar to the package substrate of an individual unit, and one or more microelectronic elements mounted to the unit substrate and connected to the terminals on the unit substrate. The individual units are stacked one above the other, with the terminals on each individual unit substrate being connected to terminals on another unit substrate by electrically conductive elements such as solder balls or pins. The terminals of the bottom unit substrate may constitute the terminals of the entire assembly or, alternatively, an additional substrate may be mounted at the bottom of the assembly which may have terminals connected to the terminals of the various unit substrates. Ball stack packages are depicted, for example, in certain preferred embodiments of U.S. Published Patent Applications 2003/0107118 and 2004/0031972, the disclosures of which are hereby incorporated by reference herein.

In another type of stack package assembly, sometimes referred to as a fold stack package, two or more chips or other microelectronic elements are mounted to a single substrate. This single substrate typically has electrical conductors extending along the substrate to connect the microelectronic elements mounted on the substrate with one another. The same substrate also has electrically conductive terminals which are connected to one or both of the microelectronic elements mounted on the substrate. The substrate is folded over on itself so that a microelectronic element on one portion lies over a microelectronic element on another portion, and so that the terminals of the package substrate are exposed at the bottom of the folded package for mounting the assembly to a circuit panel. In certain variants of the fold package, one or more of the microelectronic elements is attached to the substrate after the substrate has been folded to its final configuration. Examples of fold stacks are shown in certain preferred embodiments of U.S. Pat. No. 6,121,676; U.S. patent application Ser. No. 10/077,388; U.S. patent application Ser. No. 10/655,952; U.S. Provisional Patent Application No. 60/403,939; U.S. Provisional Patent Application No. 60/408,664; and U.S. Provisional Patent Application No. 60/408,644, the disclosures of which are hereby incorporated by reference herein. Fold stacks have been used for a variety of purposes, but have found particular application in packaging chips which must communicate with one another as, for example, in forming assemblies incorporating a baseband signal processing chip and radiofrequency power amplifier (“RFPA”) chip in a cellular telephone, so as to form a compact, self-contained assembly.

Despite all of the innovations discussed above, there remains room for improvement. For example, miniaturization of chip package assemblies is desired for use in munitions and munitions testing, among other applications. Chip assemblies for use in such applications must not only be relatively small, but also capable of withstanding relatively high G-forces. In addition to manufacturing miniaturized chip package assemblies, a method must also be devised for testing their reliability for use in such high G-force environments.

Therefore, there exists a need for a miniaturized stacked package assembly capable of withstanding harsh environments, such as high G-force applications. In addition, there is also a need for a testing fixture for testing different stacked package assemblies or individual units of the stacked packages in such a harsh environment.

### SUMMARY OF THE INVENTION

A first aspect of the present invention is a chip assembly. In accordance with several embodiments, such chip assembly may include a first unit including a first substrate and one or more first electronic components mounted to the first substrate, and a second unit including a second substrate and one or more second electronic components mounted to the second substrate. The first and second units are preferably connected together so that the first electronic components project from the first substrate toward the second substrate and the second electronic components project from the second substrate toward the first substrate, and at least some of the first electronic components extend between at least some of the second electronic components.

In certain embodiments of this first aspect, the chip assembly may further include a connection between the first and second substrates. This connection may be one or more solder balls, one or more pins, or one or more shoulder pins, among others. The shoulder pins may be substantially circular in cross section and may include a wider section flanked by two narrower sections. However, such shoulder pins may be other configurations as well. Preferably, the distance between the first and second substrates of the chip assembly is less than the total combined height of one first electronic component and one second electronic component. An encapsulant or the like may ultimately be disposed between the first and second units, so as to form a solid chip assembly. One or more spacers may also be disposed between the first and second units so as to dictate the overall height between the substrates. In its most preferred form, the chip assembly is suitable for use in high-G force operations.

A second aspect of the present invention is a testing fixture suitable for subjecting chip assemblies or packages to high-G forces. In accordance with several embodiments, such fixture may include a body including at least two detachable portions defining a hollow interior, each having at least one surface suitable for accommodating one or more chip packages. In certain embodiments, the hollow interior may include at least one horizontal surface and at least one vertical surface, and is preferably capable of withstanding high G-forces and of accommodating 48 chip packages. Of course, fixtures capable of accommodating more or less packages are contemplated. In other embodiments, the two detachable portions may be fixed together by fixation means, such as screws, and a plate portion may be disposed between the two detachable portions.

In still further embodiments of the second aspect fixture, the two detachable portions may include a can portion and a base portion, where the portions each include at least one horizontal interior surface and at least one vertical interior surface. The base portion may further include at least one vertical rib, and preferably four vertical ribs defining eight vertical interior surfaces. The two portions may be affixed to one another via fixation means, such as screws.

### BRIEF DESCRIPTION OF THE DRAWINGS

A more complete appreciation of the subject matter of the present invention and the various advantages thereof can be realized by reference to the following detailed description in which reference is made to the accompanying drawings in which:

FIG. 1 is a side perspective view of a chip assembly in accordance with one embodiment of the present invention, with encapsulant removed therefrom.

FIG. 2 is an illustration of the interconnection process of two units with one another.

FIGS. 3A-3B are illustrations depicting one assembly manufacturing process in accordance with the present invention.

FIG. 4 is an illustration of the interconnections of a plurality of assemblies with one another.

FIG. 5 is a side perspective view of a chip assembly in accordance with another embodiment of the present invention, with encapsulant removed therefrom.

FIG. 6 is a cross sectional view of a chip assembly in accordance with yet another embodiment of the present invention, in an unassembled form with encapsulant removed therefrom.

FIG. 7 is a cross sectional view of the chip assembly shown in FIG. 6, in an assembled form with encapsulant.

FIG. 8 is a top perspective of the chip assembly shown in FIGS. 6 and 7, in an assembled form.

FIG. 9 is a top perspective view of a high G-force testing fixture in accordance with one embodiment of the present invention.

FIG. 10 is a top perspective view of a cup portion of the high G-force testing fixture shown in FIG. 9.

FIG. 11 is a top perspective view of a plate portion of the high G-force testing fixture shown in FIG. 9.

FIG. 12 is a cross sectional view of the high G-force testing fixture shown in FIG. 9.

FIG. 13 is a top perspective view of a testing fixture in accordance with another embodiment of the present invention.

FIG. 14 is a bottom perspective view of the testing fixture shown in FIG. 13.

FIG. 15 is a bottom perspective view of a can portion of the testing fixture shown in FIG. 13.

FIG. 16 is a top perspective view of a base portion of the testing fixture shown in FIG. 13.

### DETAILED DESCRIPTION

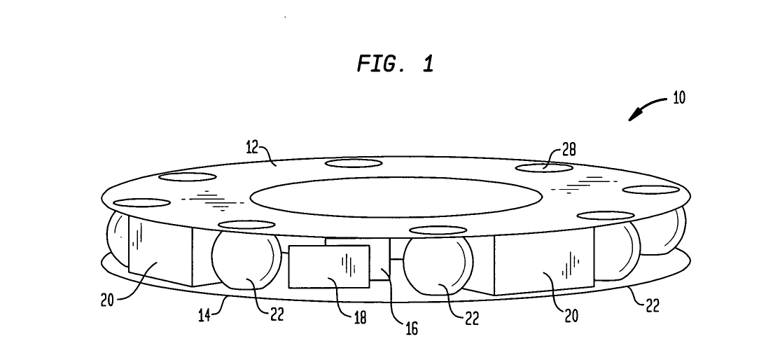

In accordance with the present invention, one miniaturized stacked package assembly is illustrated in FIG. 1, and is referred to throughout by reference numeral 10. As shown, assembly 10 includes two substrates 12 and 14, each with a plurality of electronic components, such as chips, mounted thereto. The substrate and component combination may be referred to as a unit. The components mounted to substrate 12 will be collectively referred to with reference numeral 16, and the components mounted to substrate 14 will be collectively referred to with reference numeral 18. Assembly 10 may further include spacers 20 for ensuring proper spacing between substrates 12 and 14 and solder balls 22 for connecting the substrates together. It is to be understood, that any type, size, shape or configuration substrates, components, spacers and/or solder balls may be utilized as one of ordinary skill in the art would readily recognize. For example, although depicted in the figures as having a circular shape, substrates 12 and 14 may be any shape. In addition, solder balls 22 may be solid core solder balls, or balls constructed completely of solder. Similarly, such connection elements may be pins, rods, or other structural and/or conductive elements, as will be discussed more fully below.

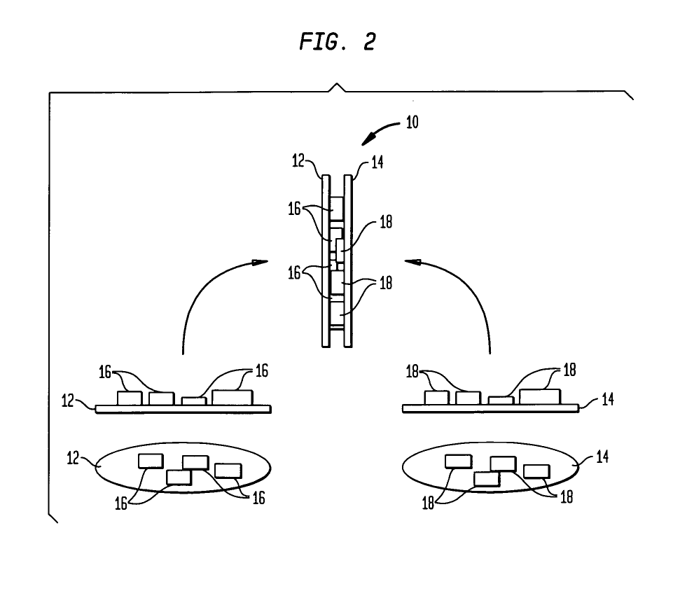

As best shown in FIG. 2, the various components 16 of substrate 12 are arranged so as to interconnect with or intersperse between the various components 18 of substrate 14, when the two substrates are sandwiched together. In the fully constructed assembly 10, the substrates are disposed so that the various electronic components face opposing substrates. Essentially, the components on each of the substrates are arranged so as to allow for a puzzle-like fit between the two complete substrates 12 and 14. In the preferred embodiment shown, it is noted that the components are collectively configured and sized, and the substrates are situated with respect to one another in a completed assembly 10, so that none of the components disposed on one substrate contacts the other substrate or any of the components thereon. However, it is clearly envisioned that other designs may include some contact between the components and opposite substrates. As shown, components 16 and 18 extend between each other in this puzzle-type fit. This allows for the distance between substrates 12 and 14 to be less than the total height of a combination of components 16 and 18.

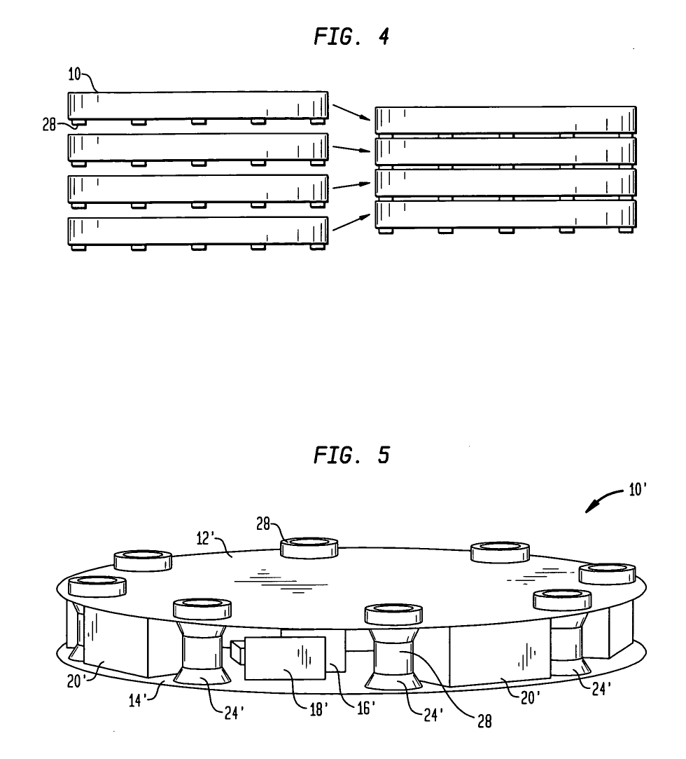

The configuration of the various components located on substrates 12 and 14, which allows the aforementioned puzzle-like fit or interconnection of the various components, also allows substrates 12 and 14 to be “stacked” or arranged with their top surfaces facing one another. This necessarily lowers the overall profile of assembly 10, which is beneficial in manufacturing and providing a reduced size assembly. In addition, this type of assembly configuration makes for a very stable and rugged package assembly 10. As best shown in FIG. 4, a completed assembly 10 is further assembled by injecting an encapsulant between substrates 12 and 14. This further stabilizes and strengthens the overall assembly 10, as well as possibly making the assembly impervious to certain environmental elements.

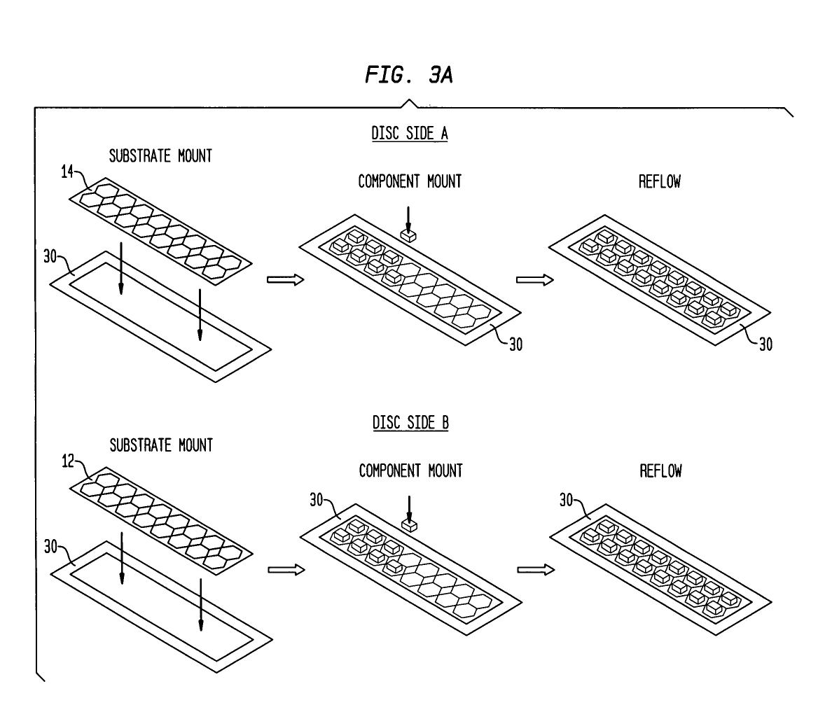

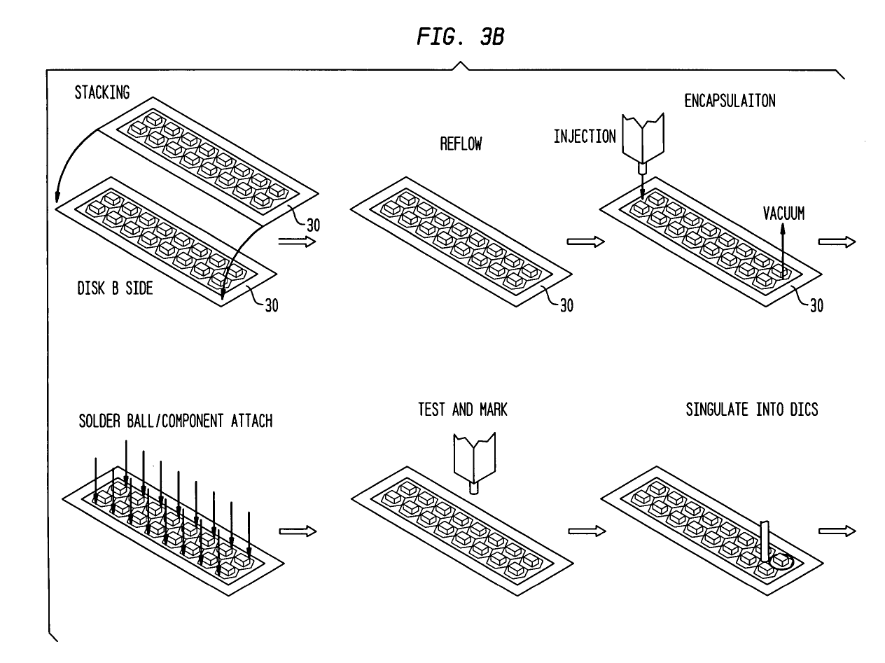

FIGS. 3A-3B depict one example process for manufacturing and assembling assembly 10. While many different techniques may be employed, the assembly process of FIGS. 3A-3B will be discussed herein. Initially, two different sheets of substrate material (which correspond to substrates 12 and 14 respectively) are each preferably mounted to a substrate mount or frame 30. Any suitable mount or frame may be utilized, and such may include top and bottom portions. It is also contemplated to provide pre-mounted substrates. Thereafter, the various electronic components are placed upon the two substrates, along with any spacers 20 or solder balls 22 to be utilized. Thus, components 16 are placed on the sheet of material corresponding to substrate 12 and components 18 are placed on the sheet of substrate material corresponding to substrate 14. This is done in the patterns necessary to allow the above described puzzle-like fit in assembly 10. With the components in place, both mounts 30 are preferably subjected to heat to cause the components to become permanently mounted to the respective sheets of material. All of these aforementioned steps are illustrated in FIG. 3A.

Once each of the mounts 30 includes sheets of substrate material having components mounted thereto, they may be stacked as mentioned above. More particularly, the top surfaces of the sheets of substrate material are sandwiched together and the various components are situated in their puzzle-like fit. Clearly, components 16 and 18 must be initially placed so as to allow such a cooperation between the two sheets of substrate material and their respective components. With the two sheets situated together, both mounts 30 are subjected to more heat to reflow any solder balls 22 that are disposed between the sheets of substrate material. This causes the two sheets to become connected together. Once this is accomplished, an encapsulant may be applied to the space between the two sheets, thus encapsulating the sheets of substrate and components therebetween. Such encapsulant may be applied by utilizing any suitable encapsulation procedures. For example, encapsulation of substrates and components in frames or mounts 30 is taught in U.S. Pat. Nos. 5,766,987, 6,046,076 and 6,329,224, the disclosures of which are hereby incorporated by reference herein.

Subsequent to the connection of the sheets of material together, and the application of encapsulant to same, solder balls, contacts or the like may be attached to at least one surface of the assembly, to allow for connection of the assemblies to circuit panels, other assemblies (shown in FIG. 4) or the like. For example, an assembly 10 employing contacts 28 is shown in FIG. 1, while a series of stacked assemblies 10 employing solder connections 28 are shown in FIG. 4. In addition, the assemblies may be tested and marked, in accordance with well known practices. Finally, individual assemblies, like the above discussed assembly 10, may be singulated from the overall assembly. Any suitable singulation procedure may be utilized, with one such procedure being taught in U.S. Provisional Application No. 60/624,667, the disclosure of which is hereby incorporated by reference herein. Essentially, this procedure involves punching out the individual assemblies 10 from the mounts or frames. Therefore, the above described process yields several assemblies 10 in accordance with the present invention. Depending upon the overall size of the sheets of substrate material utilized, the overall number of assemblies 10 may vary.

FIG. 5 depicts another embodiment assembly 10′, which includes similar elements to the above described assembly 10. Like elements are labeled with like reference numerals, only employing a “′” indicator. For example, assembly 10′ includes two substrates 12′ and 14′, which are substantially similar to substrates 12 and 14 of assembly 10. However, rather than employing solder balls 20 or the like, substrates 12′ and 14′ of assembly 10′ are connected together via pins 24′. Many different pin designs may be utilized and connected to the individual substrates by any suitable processes. Assembly 10′ also preferably includes contacts 28′, so as to allow connection of the assembly to other assemblies, circuit boards or the like.

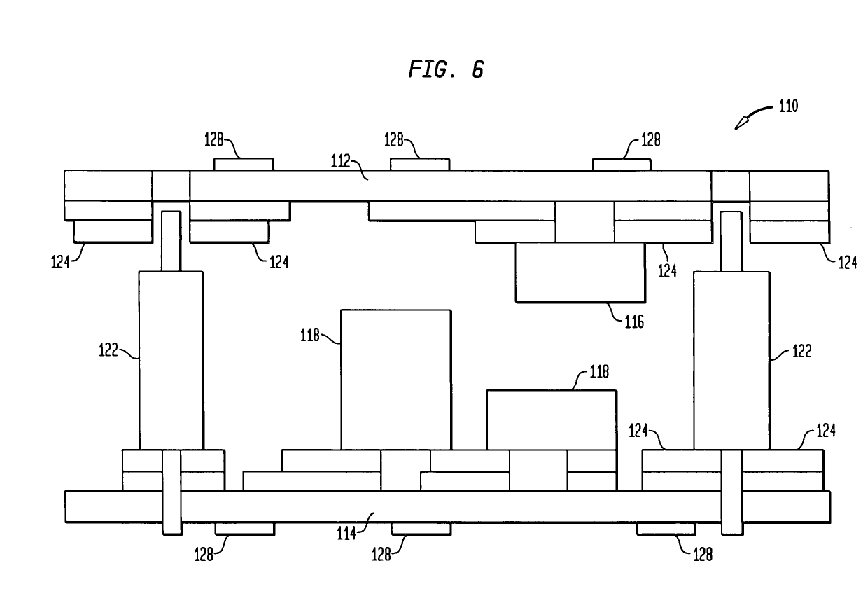

Other modes of attachment of two substrates in packages according to the present invention may be employed. In fact, any suitable method of attaching two substrates may be utilized to create assemblies, such as the above-described assemblies 10 and 10′. FIGS. 6-8 depict another assembly 110, in accordance with the present invention, which employs a different connection between its two substrates 112 and 114. It is noted that once again, like elements are labeled with like reference numerals, but this time, within the 100-series of numbers. For example, assembly 110 includes substrates 112 and 114 which each have components 116 and 118, respectively. As opposed to the above-discussed assemblies, the substrate connection utilized in assembly 110 involves the use of shoulder pins 122 between the substrates, as opposed to the above described solder balls 22 and pins 24′. In the particular embodiment shown in FIGS. 6-8, pins 122 are circular shaped with a larger diameter central section being flanked by two smaller diameter sections. The smaller diameter sections are preferably the sections which are inserted into a portion of substrates 112 and 114, and the shoulder portions formed by their cooperation with the larger section dictate the overall height or distance between the substrates. Of course, other pin configurations may be employed, including differently shaped pins and those that do not include shoulder sections. This will be more fully discussed and described below.

As is best shown in FIG. 6, pins 122 are preferably attached to substrates 112 and 114 prior to encapsulation of assembly 110. In fact, pins 122 are first preferably attached to one substrate, for example, bottom substrate 114 (see FIG. 6). This connection may be done in any suitable fashion, such as, by solder or adhesive. For example, pins 122 may first be put into contact with solder 124 on substrate 114, and thereafter subjected to a reflow process. An already attached/affixed pin 122 which has been subjected to such a reflow process is shown on the left side of FIG. 6. Of course, pins 122 may be merely placed in contact with both substrates prior to a similar reflow process which attaches/affixes the pins to both substrates 112 and 114.

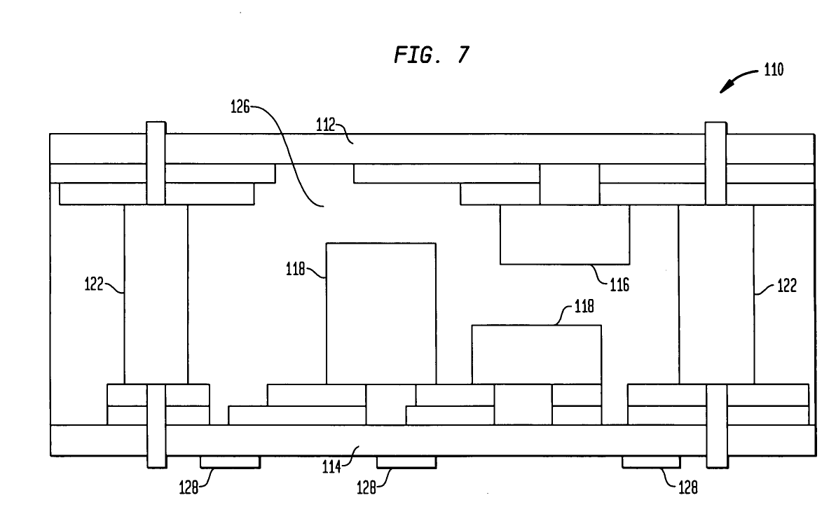

With pins 122 connected to substrate 114, substrate 112 is preferably placed over same so that pins 122 form an electrical connection between the printed circuit boards. It is noted that the placement of the substrates with respect to one another may be dictated by the overall length of pins 122, which may be varied depending upon the desired overall thickness of assembly 110. Once the desired placement is achieved, the heretofore unassembled components may be subjected to a reflow process (possibly in addition to the one discussed above) to melt solder 124 disposed on the respective substrates at or near the interconnection with pins 122. This reflow process preferably causes solder 124 to become situated in the manner shown with respect to the connection between the left side pin 122 and substrate shown in FIG. 6, and thereby creates at least one fixed connection between substrates 112 and 114. In this regard, it is noted that more than one pin 122 may be utilized to connect opposing substrates, such as the two shown in FIGS. 6 and 7.

Finally, an encapsulant 126 (best shown in FIG. 7) may be administered to fill the space between substrates 112 and 114 to form a finished assembly 110. Suitable encapsulants include epoxies or other polymeric material that exhibit flexible properties. Of course these properties are not required. Such material may be administered in accordance with any of the above-discussed methods, as well as by other methods. For example, it is contemplated to utilize a spacer block (not shown) which encompasses the space between and around substrates 112 and 114. In addition, to providing for proper spacing of the substrates, such a block may include one or more passages through which an encapsulant material may be passed. The block would preferably create a sealed off chamber that may allow for the encapsulant to cure or otherwise be contained therein. In the end, such spacer may be left in place, or be removed when the individual assembly is singulated. Such depends upon the desired finished product assembly.

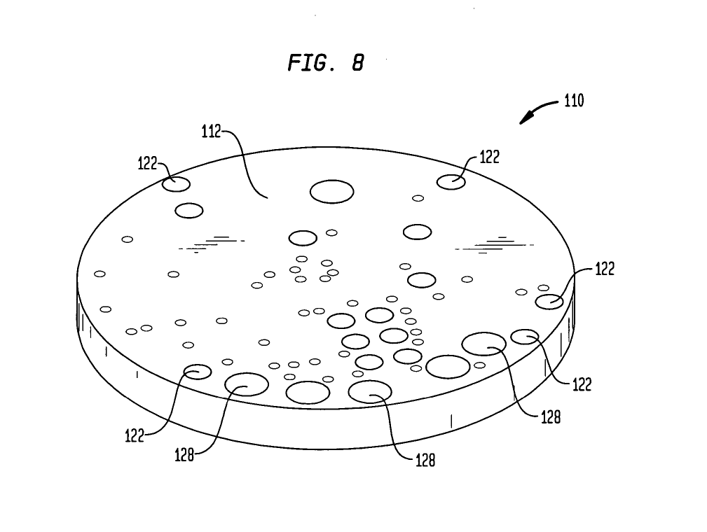

Ultimately, assembly 110 (best shown in FIG. 8) is a solid block of circuitry with some compliance due to pins 122 and encapsulant 126. In this regard, it is contemplated to construct pins 122 out of relatively flexible and/or compliant material. Of course, the particular properties of assembly 110 may widely vary. The design of assembly 110 preferably does not include any holes in either of substrates 112 and/or 114, as the particular design of pins 122 do not require such. This may aid in preventing leakage of encapsulant 126 during the assembly process of assembly 110. Depending upon the method employed in adding encapsulant 126, there may no longer exist any apertures for such encapsulant material to escape from. However, in a similar fashion to the above embodiments, it is possible to provide assembly 110 with contacts 128 to allow for the assembly to be connected with circuit boards, other assemblies or the like. Contacts 128 may be simple traces, pads, solder balls or any other suitable electrical connection. Any number of such contacts 128 may be provided on a finished assembly 110. In fact, the finished assembly 110 shown in FIG. 8 depicts a plurality of contacts 128, as well as a plurality of pins 122. Of course, other embodiments may employ more or less of each component. Finally, it is worth once again noting the pins 122 may themselves exhibit different constructions. For example, although shown in FIGS. 6 and 7 as simple shoulder pins, pins 122 may be configured differently. In addition, the overall size and shape of such pins may widely vary.

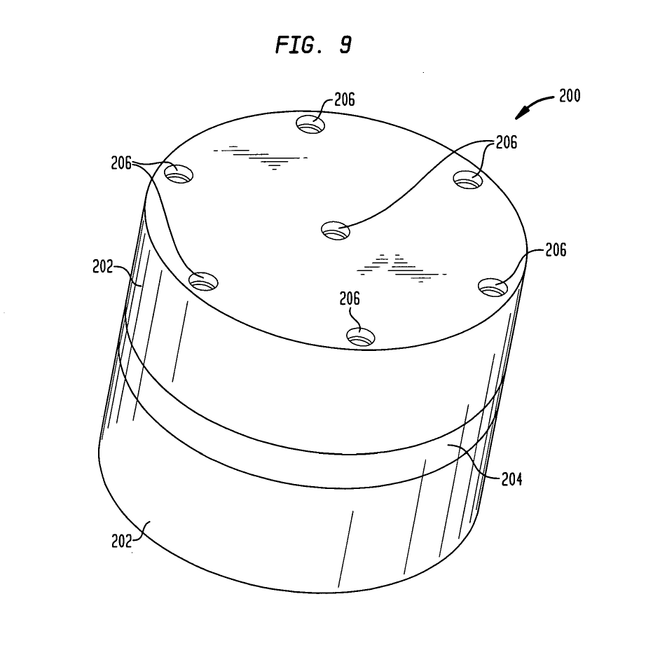

Although the above described miniaturized stacked package assemblies are suitable for use in extreme environments, such as high G-force applications, it is prudent to test any and all assembly designs for such suitability. This is the case for any type of chip package design, including but not limited to those discussed above. FIG. 9 depicts a first embodiment G-force testing fixture 200. In a preferred embodiment, fixture 200 includes two cup portions 202 and a plate portion 204. Each of these elements further includes a plurality of holes 206 extending therethrough, including a central hole (all holes labeled with reference numeral 206), so that each of the elements may be fixed together through the use of screws, posts or other fixation methods. Preferably, these fixation methods are easily removable so as to readily allow the disassembly of fixture 200.

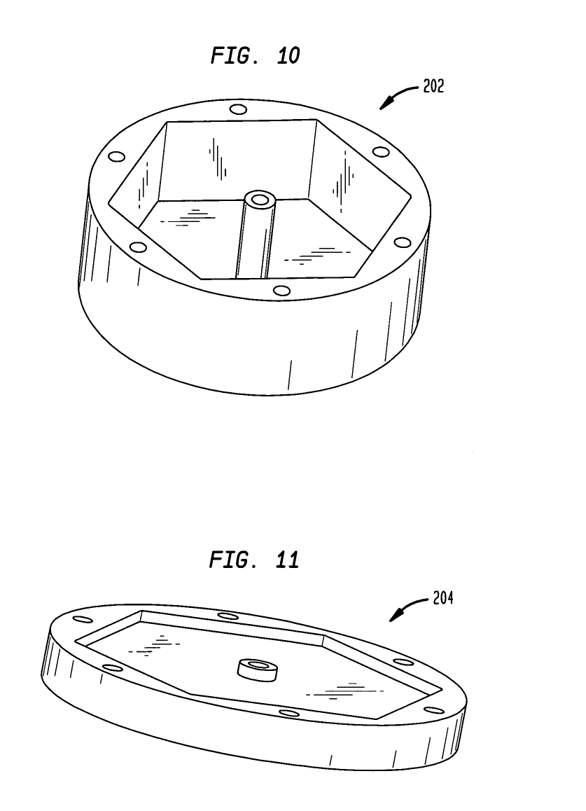

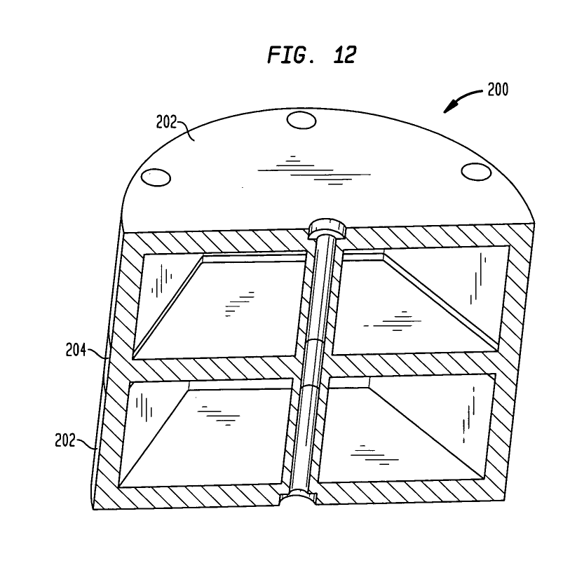

As shown in FIGS. 10 and 11, cup portions 202 and plate portion 204 include partially hollowed interiors, thereby creating and providing for several individual interior surfaces. The entire hollowed interior portion of fixture 200 is in fact best depicted in the cross sectional view of FIG. 12. These interior surfaces are adapted for allowing fixation of normally sized chip package assemblies thereto. In the particular design depicted in FIGS. 9-12, the fixture includes four horizontal surfaces and twelve vertical surfaces. The four horizontal surfaces are capable of accommodating twenty-four total chip packages of one design, and the twelve vertical surfaces are capable of accommodating twenty-four chip packages of the design. Hence, a total of 48 chip packages of one design can be mounted within fixture 200. However, this relates to one particular package design, and it is to be understood that depending upon the particular size of the chip packages, or the particular size of fixture 100, more or less packages may be contained within the testing fixture. It is also to be understood that the chip packages may be fixed within fixture 200 by any and all suitable methods, such as, by reflowing solder balls located on the chip packages or through the use of adhesive materials.

In use, fixture 200 allows for the multi-axis testing of chip packages under high G-forces. Fixture 200 is preferably loaded into and shot from a barrel or the like in order to generate the desired G-forces needed for the particular test. However, other methods of providing G-forces to the fixture are also possible. Of course, fixture 200 is constructed of materials suitable for withstanding a relatively high amount of G-forces. Depending upon which surface the individual chip packages are mounted, different forces may be applied thereto. For example, a chip package mounted to one of the aforementioned horizontal surfaces will experience different forces than a chip package mounted to one of the vertical surfaces, during a single test. Clearly, forces will vary depending upon the particular manner in which fixture 200 is subjected to the G-forces (e.g.—thrown). It is noted that if fixture 200 is shot from a barrel or the like in a similar fashion in subsequent tests, a single chip may be exposed to different forces if it is mounted to different surfaces within the fixture.

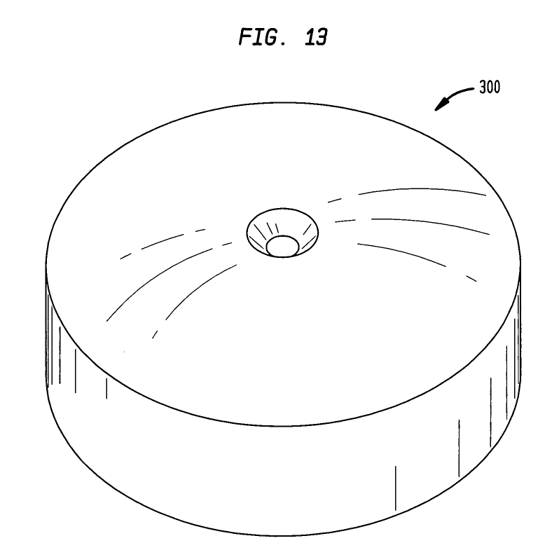

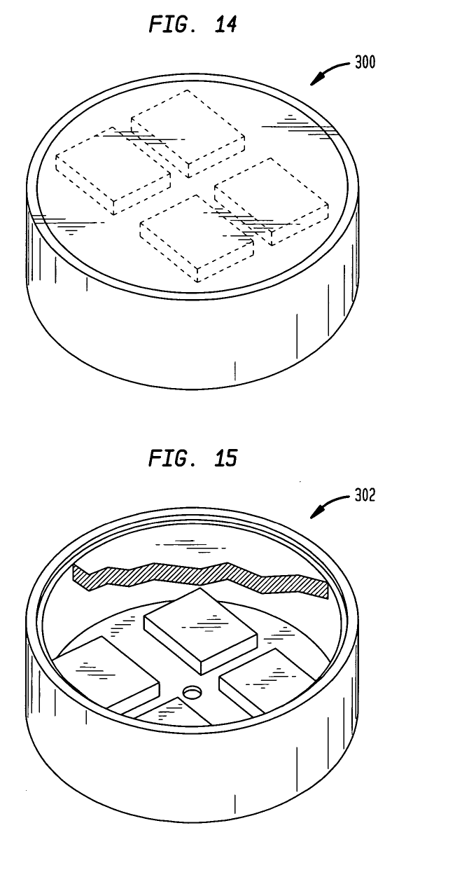

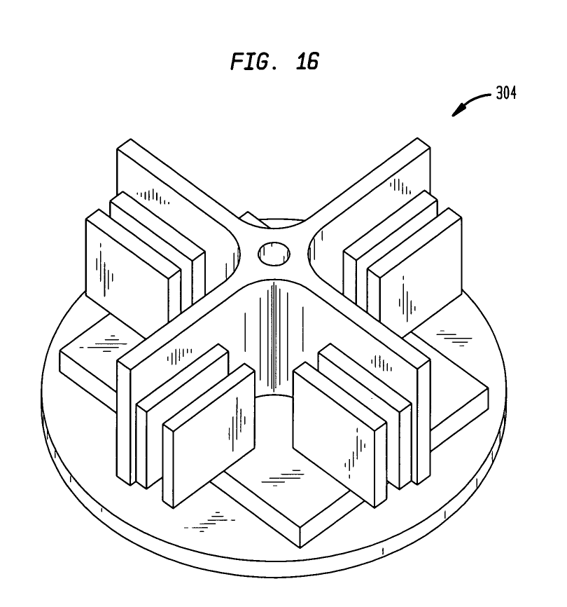

Another embodiment testing fixture 300 is shown in FIGS. 13-16. In this embodiment, fixture 300 includes a top or can portion 302 and a bottom or base portion 304. Can portion 302 includes a single horizontal surface capable of accommodating four chip packages of a particular size, and base portion 304 includes a horizontal surface capable of accommodating four chip packages of the same size and vertical ribs capable of accommodating eight packages of the same size. Thus, fixture 300 is capable of accommodating 16 chip packages. Once again, this is dependent upon one particular package size, and the total number of chips capable of being accommodated may thusly vary.

The chip packages are shown attached to the various surfaces of fixture 300 in FIG. 13-16 for illustrative purposes. The size and shape of fixture 300 and the chip packages shown in the drawings are obviously relative to one another. However, it is noted that any size and/or shape chip packages may be utilized. Upon the fixation of chip packages to the various surfaces of fixture 300, can portion 302 and base portion 304 are preferably fixed together by inserting a screw or other fixation device in a central hole 306 that extends through both portions. Preferably, the use of fixture 300 is substantially similar to that of the above described first embodiment fixture 200. As such, a detailed description of such use is not warranted here.

It is to be understood that FIGS. 9-16 depict two embodiments of testing fixtures in accordance with the present invention. However, others are envisioned. It would be clear to those of ordinary skill in the art to modify the fixtures shown in the accompanying drawings in order to accommodate more and/or different chip packages. In addition, the fixtures may be modified so as to allow for different methods of providing G-forces thereto to be utilized, or specific G-forces to be applied depending upon the given surfaces.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A chip assembly comprising:
a first unit including a first substrate and one or more first electronic components mounted to the first substrate; and
a second unit including a second substrate and one or more second electronic components mounted to the second substrate;
wherein the first and second units are connected together so that the first electronic components project from the first substrate toward the second substrate and the second electronic components project from the second substrate toward the first substrate, at least some of the first electronic components extending between at least some of the second electronic components.

2. The chip assembly according to claim 1, further comprising a connection between the first and second substrates.

3. The chip assembly according to claim 2, wherein the connection between the first and second substrates includes at least one solder ball.

4. The chip assembly according to claim 3, wherein the connection between the first and second substrates includes a plurality of solder balls.

5. The chip assembly according to claim 2, wherein the connection between the first and second substrates includes at least one pin.

6. The chip assembly according to claim 5, wherein the connection between the first and second substrates includes a plurality of pins.

7. The chip assembly according to claim 2, wherein the connection between the first and second substrates includes at least one shoulder pin.

8. The chip assembly according to claim 7, wherein the connection between the first and second substrates includes a plurality of shoulder pins.

9. The chip assembly according to claim 7, wherein each shoulder pin includes a wider section flanked by two narrower sections.

10. The chip assembly according to claim 9, wherein each shoulder pin has a substantially circular cross section.

11. The chip assembly according to claim 1, wherein a distance between the first and second substrates is less than the total combined height of one said first electronic component and one said second electronic component.

12. The chip assembly according to claim 1, further comprising an encapsulant disposed between said first and second units.

13. The chip assembly according to claim 1, further comprising at least one spacer disposed between the first and second substrates.

14. A testing fixture comprising:
a body including at least two detachable portions defining a hollow interior having at least one surface suitable for accommodating a chip package.

15. The testing fixture according to claim 14, wherein the hollow interior includes at least one horizontal surface and at least one vertical surface.

16. The testing fixture according to claim 14, wherein the at least two detachable portions are fixed together by fixation means.

17. The testing fixture according to claim 16, wherein the fixation means are screws.

18. The testing fixture according to claim 14, wherein said fixture is capable of withstanding high G-forces.

19. The testing fixture according to claim 14, wherein the hollow interior is capable of accommodating 48 chip packages.

20. The testing fixture according to claim 14, further comprising a plate portion.

21. The testing fixture according to claim 20, wherein the two detachable portions are cup portions capable of being detachably connected to the plate portion.

22. The testing fixture according to claim 21, wherein each cup portion includes at least two vertical interior surfaces.

23. The testing fixture according to claim 22, wherein the plate portion includes at least two horizontal interior surfaces.

24. The testing fixture according to claim 23, wherein the two horizontal interior surfaces are disposed on opposite sides of the plate portion.

25. The testing fixture according to claim 21, wherein each cup portion includes six vertical interior surfaces and the plate portion includes two horizontal interior surfaces.

26. The testing fixture according to claim 14, wherein the two detachable portions includes a can portion and a base portion.

27. The testing fixture according to claim 26, wherein the can portion includes at least one horizontal interior surface and at least one vertical interior surface.

28. The testing fixture according to claim 27, wherein the base portion includes at least one horizontal interior surface and at least one vertical interior surface.

29. The testing fixture according to claim 27, wherein the base portion includes at least one vertical rib.

30. The testing fixture according to claim 29, wherein the base portion includes four vertical ribs defining eight vertical interior surfaces.

31. The testing fixture according to claim 26, wherein the can portion and the base portion are fixed together by fixation means.

32. The testing fixture according to claim 31, wherein the fixation means are screws.
